(19) United States
(12) Patent Application Publication
(10) Pub. No.: US 2026/0188620 A1
(43) Pub. Date: Jul. 2, 2026

(54) ELECTRIC FIELD GENERATION PORTION AND SUBSTRATE TREATMENT APPARATUS

(71) Applicant: SAMSUNG ELECTONICS CO., LTD., Suwon-si (KR)

(72) Inventors: Myung Mo AHN, Suwon-si (KR); Youngsu Noh, Suwon-si (KR); Jingyu Park, Suwon-si (KR)

(73) Assignee: SAMSUNG ELECTONICS CO., LTD., Suwon-si (KR)

(21) Appl. No.: 19/391,501

(22) Filed: Nov. 17, 2025

(30) Foreign Application Priority Data
Jan. 2, 2025 (KR) 10-2025-0000228

(51) Int. Cl. H01J 37/32

(52) U.S. Cl. CPC H01J 37/32174; H01J 37/32568

(57) ABSTRACT

An electric field generator configured to generate an electric field in a processing space where a substrate is processed, including: an electrode having a surface facing a substrate in the processing space; and a power supply that supplies RF power to the electrode, in which the electrode comprises a first electrode and a second electrode that are spaced apart from each other, in which the power supply includes: a first power supply that supplies RF power to the first electrode; and a second power supply that supplies RF power to the second electrode, in which the first power supply supplies RF power at a first intensity and the second power supply supplies RF power at a second intensity different from the first intensity.

### CROSS-REFERENCE TO RELATED APPLICATION

This application claims priority under 35 U.S.C. § 119 to Korean Patent Application No. 10-2025-0000228, filed on January 02, 2025, in the Korean Intellectual Property Office, the disclosure of which is incorporated by reference herein in its entirety.

### BACKGROUND

### 1. Field

The present disclosure relates to an electric field generation portion that forms an electric field in a processing space for processing a substrate, and more particularly, to an electric field generation portion including an electrode in which RF (Radio Frequency) power of different intensities is applied to a plurality of areas, and a substrate treatment apparatus including the same.

### 2. Description of Related art

Generally, warpage of a substrate such as a semiconductor may occur due to thermal stress, etc., during the process of processing the substrate. Such warpage may cause defects of the substrate. Therefore, compensation or prevention of the warpage must be performed.

In particular, when tensile stress is applied to parts of a side surface of a substrate, and compressive stress is applied to other parts of the substrate, warpages may occur to the substrate in multiple directions, such as a saddle-shaped warp in which parts of the substrate are curved in a front side surface direction of the substrate in a direction approaching the ends of the parts, and the other parts of the substrate are curved in a back side surface direction of the substrate in a direction approaching the ends of the other parts. Compensation and prevention of such warpages in multiple directions is very complicated.

### SUMMARY

Embodiments of the present disclosure provide an electric field generator that compensates and prevents warpage of various shapes of a substrate and a substrate treatment apparatus including the same.

According to an aspect of the disclosure, an electric field generator configured to generate an electric field in a processing space where a substrate is processed, including: an electrode having a surface facing a substrate in the processing space; and a power supply that supplies RF power to the electrode, in which the electrode comprises a first electrode and a second electrode that are spaced apart from each other, in which the power supply includes: a first power supply that supplies RF power to the first electrode; and a second power supply that supplies RF power to the second electrode, in which the first power supply supplies RF power at a first intensity and the second power supply supplies RF power at a second intensity different from the first intensity.

According to an aspect of the disclosure, a substrate treatment apparatus configured to treat a substrate, the substrate treatment apparatus including: a chamber having a processing space in which a substrate is processed; a substrate support that supports a substrate within the processing space; a gas supplier that supplies a process gas; and an electric field generator that generates an electric field in the processing space, in which the electric field generator includes: an electrode having a surface facing a substrate in the processing space; and a power supply that supplies RF power to the electrode, in which the electrode comprises a first electrode and a second electrode that are spaced apart from each other, in which the power supply includes: a first power supply that supplies RF power to the first electrode; and a second power supply that supplies RF power to the second electrode, in which the first power supply supplies RF power at a first intensity and the second power supply supplies RF power at a second intensity different from the first intensity.

According to an aspect of the disclosure, a substrate treatment apparatus configured to treat one or more substrates, the substrate treatment apparatus including: a chamber having a processing space in which a substrate is processed; a substrate support that supports a substrate within the processing space; a gas supplier that supplies a process gas; a plasma generation apparatus that converts the process gas into plasma; and an electric field generator that generates an electric field in the processing space, in which the substrate support comprises a stage that supports a substrate on a surface of the stage, in which the electric field generator includes: an electrode having a surface facing a substrate in the processing space and embedded in the stage; and a power supply that supplies RF power to the electrode, in which the electrode comprises a first electrode and a second electrode that are spaced apart from each other, in which the power supply includes: a first power supply that supplies RF power to the first electrode; and a second power supply that supplies RF power to the second electrode, in which the first power supply supplies RF power at a first intensity and the second power supply supplies RF power at a second intensity different from the first intensity.

### BRIEF DESCRIPTION OF DRAWINGS

The above and other features of the present disclosure will be more clearly understood from the following detailed description, taken in conjunction with the accompanying drawings.

FIG. 1 is a vertical cross-sectional view illustrating a substrate treatment apparatus according to some example embodiments of the present disclosure.

FIG. 2 is a perspective view illustrating an example of a substrate that may be processed by the substrate treatment apparatus of FIG. 1.

FIG. 3 is a plan view illustrating an example of the back side surface of the substrate of FIG. 2, of which parts are divided according to the warpage direction.

FIG. 4 is a plan view illustrating an example of the electrode of FIG. 1.

FIG. 5 is a plan view illustrating another example of the electrode of FIG. 1.

FIG. 6 is a plan view illustrating an example of the back side surface of a substrate having warpage parts corresponding to the electrode of FIG. 5.

FIG. 7 is a plan view illustrating an electrode according to some example embodiments of the present disclosure.

FIG. 8 is a plan view illustrating an example of the back side surface of a substrate having warpage parts corresponding to the electrode of FIG. 7.

FIGS. 9 to 13 are vertical cross-sectional views illustrating substrate treatment apparatuses according to some example embodiments of the present disclosure, respectively.

### DETAILED DESCRIPTION OF EMBODIMENTS

Hereinafter, embodiments of the present disclosure will be described in detail and with sufficient clarity for those skilled in the art to easily implement the embodiments of the present disclosure. The embodiments described herein are non-limiting example embodiments, and thus, the disclosure is not limited thereto and may be realized in various other forms.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

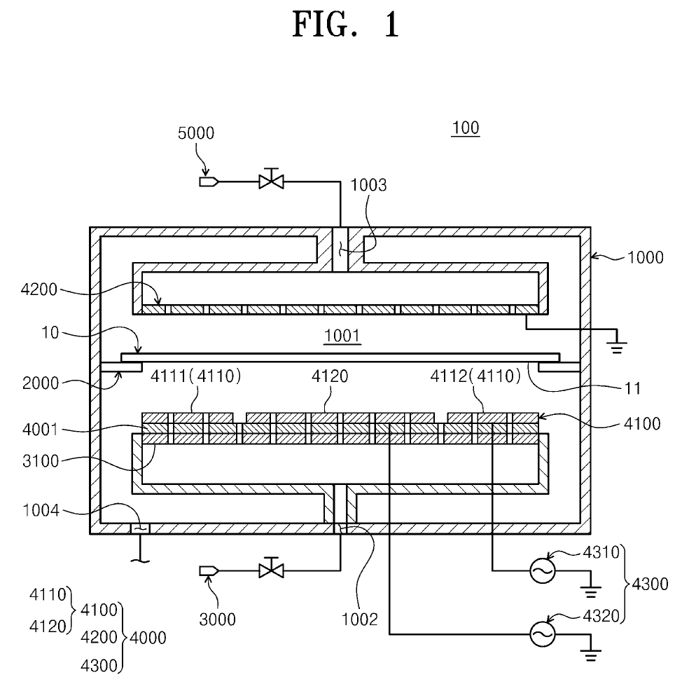

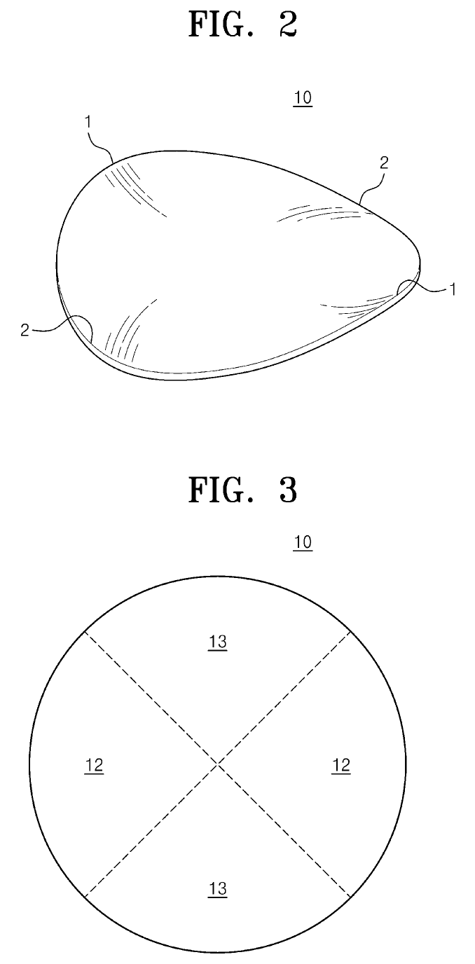

FIG. 1 is a vertical cross-sectional view illustrating a substrate treatment apparatus 100 according to some example embodiments of the present disclosure. FIG. 2 is a perspective view illustrating an example of a substrate 10 that may be processed by the substrate treatment apparatus 100 of FIG. 1. FIG. 3 is a plan view illustrating an example of the back side surface 11 of the substrate 10 of FIG. 2, of which parts are divided according to the warpage direction.

Referring to FIGS. 1 to 3, the substrate treatment apparatus 100 may process a substrate 10. The substrate 10 may be various types of semiconductor substrates such as a wafer or glass. The substrate 10 may have a disc structure of various diameters. The substrate treatment apparatus 100 may be an apparatus that performs a deposition process on the substrate 10.

The higher the density of the deposited film in the parts of the substrate 10, the stronger the tensile stress generated on the deposited surface, and the lower the density of the deposited film in the parts of the substrate 10, the stronger the compressive stress generated on the deposited surface. Using this principle, the substrate treatment apparatus 100 may prevent or compensate for warpage of the substrate 10 in various directions by depositing a film with different densities on each part of the back side surface 11 of the substrate 10.

In one or more examples, the substrate treatment apparatus 100 may compensate for or prevent convex warpage of parts of a substrate 10 in the direction in which the back side surface 11 of the substrate 10 faces by depositing a film at a high density to generate tensile stress on the back side surface of the parts of the substrate 10. In one or more examples, the substrate treatment apparatus 100 may compensate for or prevent convex warpage of other parts of a substrate 10 in the direction in which the front side surface of the substrate 10 faces by depositing a film at a low density to generate compressive stress on the back side surface of the other parts of the substrate 10. For example, the substrate treatment apparatus 100 may deposit a film made of a material such as silicon nitride or silicon oxide at different densities for each part on the back side surface 11 of the substrate 10.

Warpage may occur in a substrate 10 during the semiconductor manufacturing process. For example, as illustrated in FIG. 3, parts 12 of a substrate 10 may be bent toward the direction in which the back side surface 11 of the substrate 10 faces as approaching each end of the parts 12. In contrast, other parts 13 of the substrate 10 may be bent toward the direction in which the front side surface of the substrate 10 faces as approaching each end of the other parts 13. In some example embodiments, as illustrated in FIG. 2, a saddle-shaped warpage may occur in the substrate 10 of which both ends 1 facing in a direction parallel to a first direction and other both ends 2 facing in a second direction perpendicular to the first direction are bent in opposite directions.

The substrate treatment apparatus 100 according to the embodiments of the present disclosure may be not limited thereto and may compensate for or prevent warpage of various shapes of the substrate 10.

The substrate treatment apparatus 100 may be a capacitively coupled plasma (CCP) type. However, as understood by one of ordinary skill in the art, the embodiments are not limited to this configuration and may include other types of plasma generation apparatuses. According to some example embodiments, the substrate treatment apparatus 100 may include a chamber 1000, a substrate support 2000, a gas supplier 3000, an electric field generator 4000 and a purge gas supplier 5000. The substrate treatment apparatus 100, according to some example embodiments of the present disclosure, may further include other essential or optional components such as a capacitor, a matcher, a door and/or a heater.

The chamber 1000 may have a processing space 1001 therein. A substrate 10 may be processed in the processing space 1001. A process gas supply hole 1002 through which a process gas is introduced into the processing space 1001 may be formed on the bottom wall of the chamber 1000. A purge gas supply hole 1003 through which a purge gas is introduced into the processing space 1001 may be formed on the ceiling wall of the chamber 1000. In addition, an exhaust hole 1004 through which residual gas and byproducts after a process in the processing space 1001 are discharged to the outside may be formed on the bottom wall of the chamber 1000. A pump that provides power to discharge residual gas and by-products and/or a scrubber that captures the discharged gas and by-products may be connected to the exhaust hole 1004.

The substrate support 2000 may support a substrate 10 within the processing space 1001. According to some example embodiments, the substrate support 2000 may support the substrate 10 such that the front side surface and back side surface 11 of the substrate 10 are spaced apart from the ceiling wall and the bottom wall of the chamber 1000. For example, the substrate support 2000 may include holders that protrude from the side walls of the chamber 1000 toward the center of the processing space 1001 and support the edge area of the back side surface 11 of the substrate 10 at the ends of the holders. The substrate support 2000 may be not limited thereto and may have various configurations and structures.

The gas supplier 3000 may supply a process gas to the processing space 1001. According to some example embodiments, the process gas may be various types of gas or gases that may react within the processing space 1001 to form an oxide film or nitride film, such as SiH₄, N₂O, O₂ and/or NH₃. According to some example embodiments, the gas supplier 3000 may supply the process gas into the processing space 1001 through the bottom wall of the chamber 1000. For example, the gas supplier 3000 may supply the process gas into the processing space 1001 through the process gas supply hole 1002.

The electric field generator 4000 may form an electric field in the processing space 1001. According to some example embodiments, the electric field formed by the electric field generator 4000 may convert the process gas into plasma within the processing space 1001. According to some example embodiments, the electric field generator 4000 may include an electrode 4100, a ground electrode 4200 and a power supply 4300.

A side surface of the electrode 4100 may face the substrate 10 which is placed in the processing space 1001. The electrode 4100 may include a plurality of electrodes 4110, 4120 which are spaced apart from each other and electrically separated from each other when looking at the side surface. The electrodes 4110, 4120 may be combined with each other to form a shape corresponding to the substrate 10. According to some example embodiments, the electrodes 4110, 4120 may be combined with each other to form a circular structure. Each of the electrodes 4110, 4120 may have a mesh structure. The structure of the electrode 4100 may be not limited thereto. In one or more examples, the electrode 4100 may have various structures as needed. For example, each structure of the electrodes 4110, 4120 may be a plate structure. The electrodes 4110, 4120 may be made of conductor or conductors.

According to some example embodiments, the electrode 4100 may include a first electrode 4110 and a second electrode 4120. The first electrode 4110 and the second electrode 4120 may be arranged to be spaced apart from each other when looking at the side surface of the electrode 4100.

According to some example embodiments, the electrode 4100 may be on a surface of the shower head 3100 facing the substrate 10. The process gas supplied through the process gas supply hole 1002 may be distributed and supplied into the processing space 1001 through the shower head 3100. A plurality of injection holes, through which the process gas may pass, may be arranged in the shower head 3100. The shower head 3100 may be made of a metal material that conducts electricity. In some example embodiments, a nonconductor layer made of a nonconductor or nonconductors may be coated on the surface of the shower head 3100 facing the substrate 10 to electrically isolate each of the electrodes 4110, 4120. In one or more examples, electrodes 4110, 4120 may be on a surface of the nonconductor layer 4001 facing the substrate 10.

The ground electrode 4200 may face the electrode 4100 with the substrate 10 interposed therebetween. The ground electrode 4200 may be grounded. According to some example embodiments, the ground electrode 4200 may be a purge gas shower head. The purge gas supplied through the purge gas supply hole 1003 may be distributed and supplied into the processing space 1001 through the purge gas shower head 5100. A plurality of injection holes through which the purge gas pass may be arranged in the purge gas shower head 5100. The purge gas shower head 5100 may be made of a metal material that conducts electricity.

The power supply 4300 may supply RF power to the electrode 4100. The power supply 4300 may apply power of different intensities to each of the electrodes 4110, 4120. According to some example embodiments, the power supply 4300 may include a first power supply 4310 and a second power supply 4320.

According to some example embodiments, the first power supply 4310 may supply RF power to the first electrode 4110. The second power supply 4320 may supply RF power to the second electrode 4120. The first power supply 4310 and the second power supply 4320 may supply RF power of different intensities to the first electrode 4110 and the second electrode 4120, respectively. The first power supply 4310 and the second power supply 4320 may control the intensity of power by controlling the magnitude of voltage and/or current.

The greater the power supplied to the electrode for forming plasma, the more plasma may be induced and the higher density deposition layer may be formed in a deposition apparatus of the capacitively coupled plasma (CCP) type. Therefore, the first power supply 4310 and the second power supply 4320 may control the deposition density of the first electrode 4110 and the second electrode 4120 differently by supplying power of different intensities to the first electrode 4110 and the second electrode 4120, respectively.

The purge gas supplier 5000 may supply purge gas into the processing space 1001. According to some example embodiments, the purge gas may be an inert gas such as N₂ or Ar. According to some example embodiments, the purge gas supplier 5000 may supply the purge gas toward the front side surface of the substrate 10 through the ceiling wall of the chamber 1000. For example, the purge gas supplier 5000 may supply purge gas into the processing space 1001 through the purge gas supply hole 1003. the plasma for depositing the back side surface 11 of the substrate 10 may be pushed out to prevent the plasma from reaching the front side surface of the substrate 10 by supplying the purge gas toward the front side surface of the substrate 10 as described above. In one or more examples, a purge gas may be an inert, dry gas, most commonly nitrogen or argon, used to displace unwanted or hazardous gases from a system.

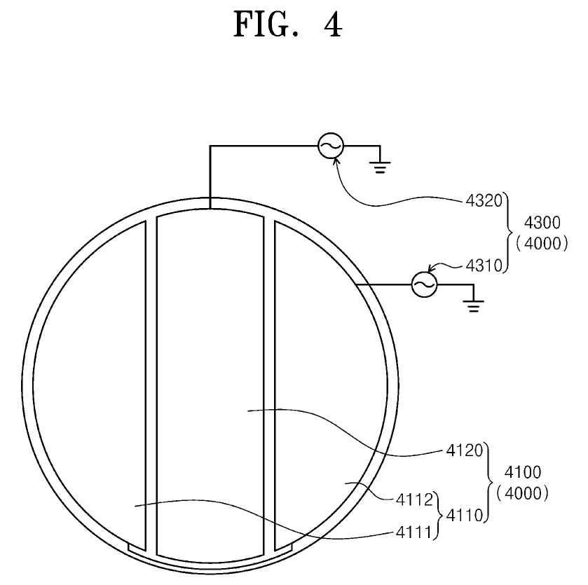

FIG. 4 is a plan view illustrating an example of the electrode 4100 of FIG. 1.

Referring to FIGS. 1 to 4, the first electrode 4110 may include a first side electrode 4111 and a second side electrode 4112. The first side electrode 4111 and the second side electrode 4112 may be arranged to be spaced apart from each other in a direction when looking at the side surface of the substrate 10 (e.g., direction perpendicular to the plan view). The second electrode 4120 may be between the first side electrode 4111 and the second side electrode 4112. The first side electrode 4111 and the second side electrode 4112 may be electrically connected to each other by bypassing the second electrode 4120. The boundary area between the first side electrode 4111 and the second electrode 4120, and the boundary area between the second side electrode 4112 and the second electrode 4120 may have a straight structure parallel to each other.

The structure of the first electrode 4110 and the second electrode 4120 may correspond to a case in which the arrangement direction of the parts 12 of the substrate 10 and the arrangement direction of the other parts 13 of the substrate 10 intersect each other perpendicularly, and the direction of the warpage occurring in the parts 12 of the substrate 10 and the direction of the warpage occurring in the other parts 13 of the substrate 10 are opposite to each other, as in the substrate 10 illustrated in FIG. 3. The direction in which the other parts 13 of the substrate 10 are arranged and the direction in which the first side electrode 4111 and the second side electrode 4112 are arranged may correspond to each other.

For example, the deposition density of the other parts 13 of the back side surface 11 of the substrate 10 corresponding to the first electrode 4110 may become higher than the deposition density of the parts 12 when the first power supply 4310 supplies RF power of greater intensity than the second power supply 4320 during the deposition process of the substrate treatment apparatus 100. Accordingly, tensile stress may be applied to the other parts 13 of the back side surface 11 of the substrate 10, and compressive stress may be applied to the parts 12. Therefore, if the deposition process of the example described above is performed on a substrate 10 that is warped or has the potential to be warped due to stress occurring in the direction opposite to the stresses by the deposition during a semiconductor manufacturing process, warpage of the substrate 10 may be prevented or compensated for.

In contrast, the deposition density of the other parts 13 of the back side surface 11 of the substrate 10 corresponding to the first electrode 4110 may be lower than the deposition density of the parts 12 of the substrate 10 when the first power supply 4310 supplies RF power of lower intensity than the second power supply 4320 during the deposition process of the substrate treatment apparatus 100. Accordingly, compressive stress is applied to the other parts 13 of the back side surface 11 of the substrate 10, and tensile stress is applied to the parts 12 of the back side surface 11 of the substrate 10. Therefore, if the deposition process of the example described above is performed on a substrate 10 that is warped or has the potential to be warped due to stress occurring in the direction opposite to the stresses by the deposition during a semiconductor manufacturing process, warpage of the substrate 10 may be advantageously prevented or compensated for.

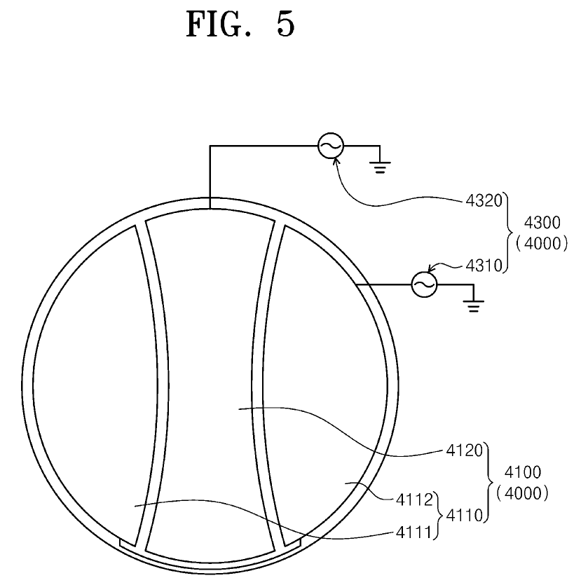

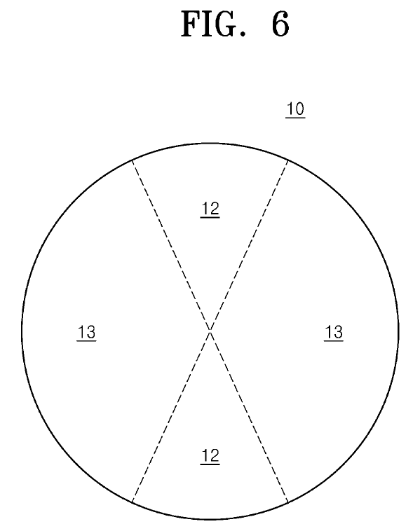

FIG. 5 is a plan view illustrating another example of the electrode 4100 of FIG. 1. FIG. 6 is a plan view illustrating an example of the back side surface 11 of a substrate 10 having warpage parts corresponding to the electrode 4100 of FIG. 5.

Referring to FIG. 5 and FIG. 6, when the range of the parts 12 of the back side surface 11 of the substrate 10 and the other parts of the back side surface 13 of the substrate 10 are different as illustrated in FIG. 6, the range of each of the first electrode 4110 and the second electrode 4120 may also be different correspondingly. For example, if the range of the other parts 13 of the back side surface 11 of the substrate 10 is wider toward the parts 12 compared to the case of FIG. 3, the boundary area between the first side electrode 4111 and the second electrode 4120, and the boundary area between the second side electrode 4112 and the second electrode 4120 may have a curved structure that is convexly bent toward each other to widen the area of the first electrode 4110, correspondingly.

As understood by one of ordinary skill in the art, other configurations, structures, functions, deposition methods, etc. of the substrate treatment apparatus including the electrode 4100 of FIG. 5 may be identical or similar to the other embodiments described above.

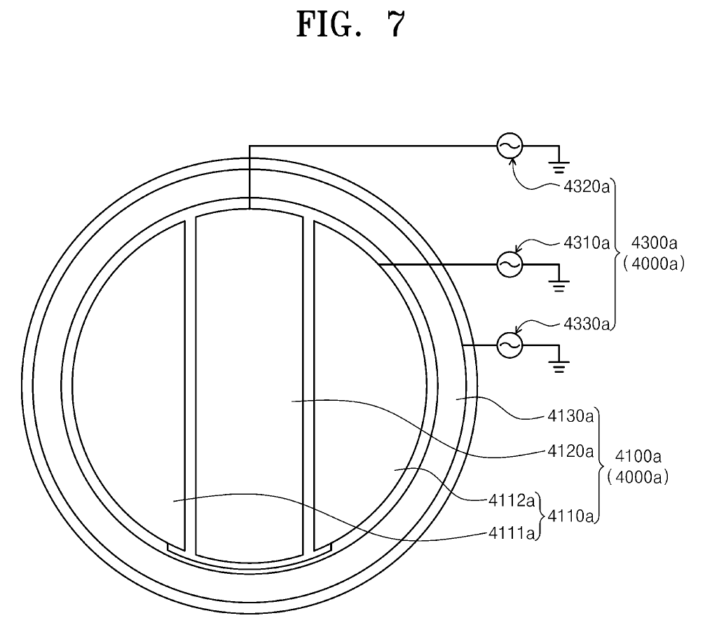

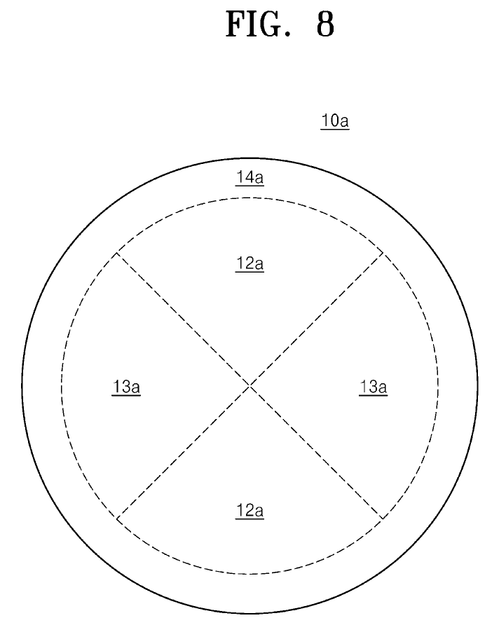

FIG. 7 is a plan view illustrating an electrode 4100a according to some example embodiments of the present disclosure. FIG. 8 is a plan view illustrating an example of the back side surface of a substrate 10a having warpage parts corresponding to the electrode 4100a of FIG. 7.

Referring to FIGS. 7 and 8, the substrate 10a may have three or more parts that are warped in different directions and/or degrees during the manufacturing process. For example, as illustrated in FIG. 8, the substrate 10a may include parts 12a and other parts 13a in the central area of the substrate 10a, which have similar arrangements, ranges, and directions and degrees of warpage as in FIG. 3 or FIG. 6. In one or more examples, warpage of different direction and/or degree from that in the parts 12a and the other parts 13a may occur in an edge area 14a of the substrate 10a.

Correspondingly, the electrode 4100a may further include a third electrode 4130a. The third electrode 4130a may surround the first electrode 4110a and the second electrode 4120a, and be spaced apart from the first electrode 4110a and the second electrode 4120a, when looking at the above-mentioned surface of the substrate 10. The third electrode 4130a may electrically isolated from the first electrode 4110a and the second electrode 4120a.

In one or more examples, the power supply 4300a may further include a third power supply 4330a. The third power supply 4330a may supply RF power to the third electrode 4130a. According to some example embodiments, the third power supply 4330a may supply RF power of a different intensity from that of the first power supply 4310a or the second power supply 4320a to the third electrode 4130a. The third power supply 4330a may supply RF power of a different intensity from that of the first electrode 4110a or the second electrode 4120a to the third electrode 4130a depending on the direction and degree of warpage of the edge area 14a of the substrate 10.

The arrangement, range, structure, etc. of the first electrode 4110a and the second electrode 4120a of FIG. 7 may be identical or similar to the electrode 4100 of FIG. 4 or FIG. 5.

As understood by one of ordinary skill in the art, other configurations, structures, functions, deposition methods, etc. of the substrate treatment apparatus including the electrode 4100a of FIG. 7 may be identical or similar to the other embodiments described above.

In FIGS. 4, 5, and FIG. 7, the portions of the first electrode 4110, 4110a, the second electrode 4120, 4120a and the third electrode 4130a corresponding to the injection holes are open, but the open portions are not illustrated for convenience.

The corresponding relationship between the shapes of the electrodes 4100, 4100a and the parts 12, 12a, the other parts 13, 13a and the area 14 of the substrate 10, 10a of FIGS. 3 to 8 described above are only examples, therefore the number or structure of the electrodes 4110, 4110a, 4120, 4120a, 4130a and/or the structure or configuration of the power supply 4300, 4300a may be not limited thereto. As understood by one of ordinary skill in the art, the structure, number and size of each of the electrodes of the substrate treatment apparatus, and the structure, configuration and/or power values of the power supplys according to the example embodiments of the present disclosure may be variously set by simulation and/or test operation depending on the type of the substrate 10 and/or the shape of the warpage, etc.

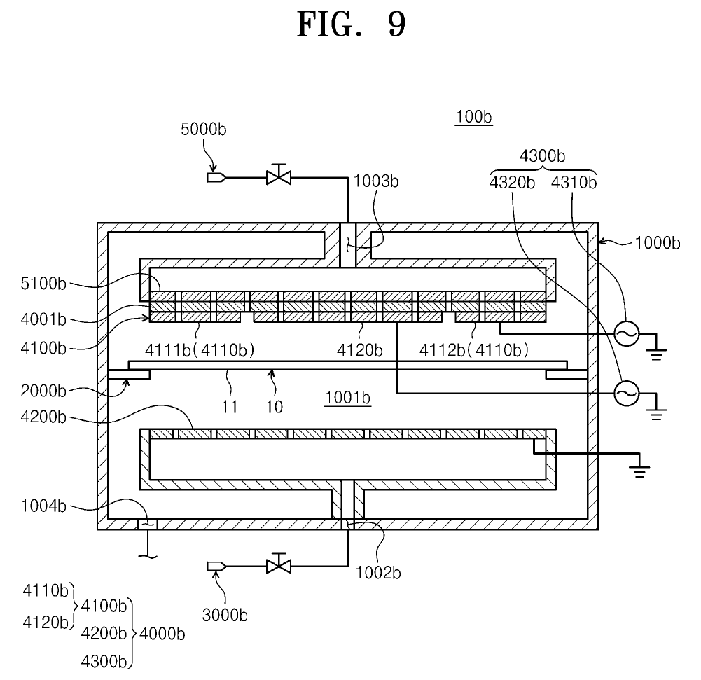

FIG. 9 is a vertical cross-sectional view illustrating a substrate treatment apparatus 100b according to some example embodiments of the present disclosure.

Referring to FIG. 9, an electrode 4100b may be located on a surface of a purge gas shower head 5100b facing the substrate 10. A process gas supplied through a purge gas supply hole 1003b may be distributed and supplied into a processing space 1001b through the purge gas shower head 5100b. The purge gas shower head 5100b may be made of a metal material that conducts electricity. In some example embodiments, a nonconductor layer 4001b made of a nonconductor or nonconductors may be coated on the surface of the purge gas shower head 5100b facing the substrate 10 to electrically isolate each of the electrodes 4110b, 4120b. In one or more examples, the electrodes 4110b, 4120b may be on the surface of the nonconductor layer 4001b facing the substrate 10.

According to some example embodiments, the ground electrode 4200b may be a shower head. The process gas supplied through the process gas supply hole 1002b may be distributed and supplied into the processing space 1001b through the shower head 4200b. The shower head 4200b may be made of a metal material that conducts electricity.

As understood by one of ordinary skill in the art, other configurations, structures, functions, deposition methods, etc. of the substrate treatment apparatus 100b of FIG. 9 may be identical or similar to the other embodiments described above.

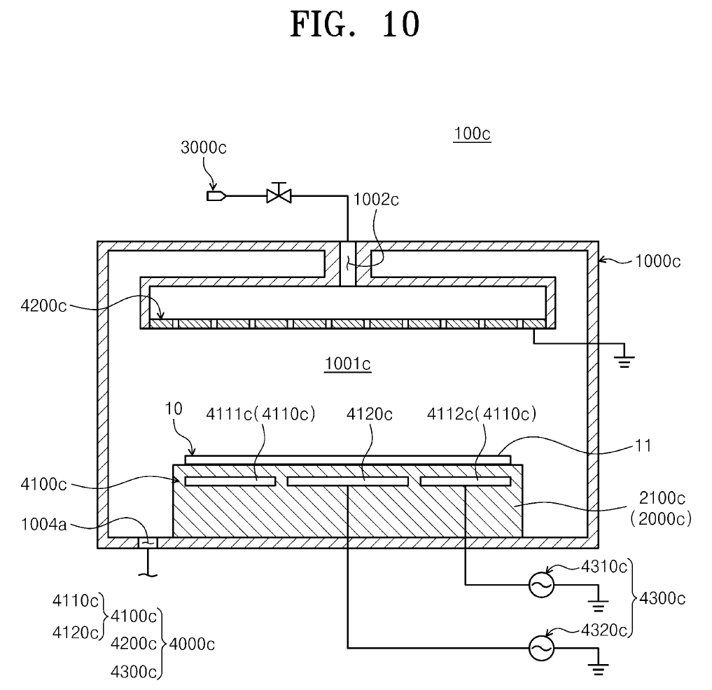

FIG. 10 is a vertical cross-sectional view illustrating a substrate treatment apparatus 100c according to some example embodiments of the present disclosure.

Referring to FIG. 10, a substrate support 2000c may include a stage 2100c that supports the substrate 10 on the upper surface of the stage 2100c. In some example embodiments, the substrate 10 may be placed on the stage 2100c with the back side surface 11 of the substrate 10 facing upward to make the deposition be performed on the back side surface 11. Accordingly, the components for supplying the purge gas of FIG. 1 may not be provided, since the front side surface of the substrate 10 is covered by the stage 2100c. The electrode 4100c may be embedded in the stage 2100c.

According to some example embodiments, the gas supplier 3000c may supply process gas through the ceiling wall of the chamber 1000c. Therefore, a process gas supply hole 1002c may be formed in the ceiling wall of the chamber 1000c. The ground electrode 4200c may be a shower head that distributes the process gas and supplies the process gas to the processing space 1001c.

Other configurations, structures, functions, deposition methods, etc. of the substrate treatment apparatus 100c of FIG. 10 may be identical or similar to the other embodiments described above.

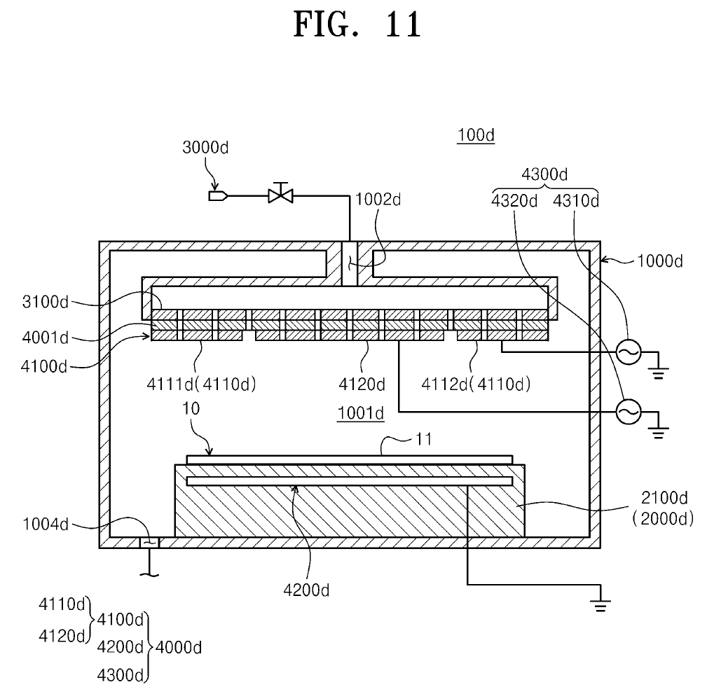

FIG. 11 is a vertical cross-sectional view illustrating a substrate treatment apparatus 100d according to some example embodiments of the present disclosure.

Referring to FIG. 11, the substrate support 2000d may include a stage 2100d that supports a substrate 10 on the upper surface of the stage 2100d. In some example embodiments, the substrate 10 may be placed on the stage 2100d with the back side surface 11 of the substrate 10 facing upward to make the deposition be performed on the back side surface 11. Accordingly, the components for supplying the purge gas of FIG. 1 may not be provided, since the front side surface of the substrate 10 is covered by the stage 2100d. The ground electrode 4200d may be embedded in the stage 2100d.

According to some example embodiments, the gas supplier 3000d may supply the process gas through the ceiling wall of the chamber 1000d. Therefore, a process gas supply hole 1002d may be formed in the ceiling wall of the chamber 1000d.

The electrode 4100d may be on the surface of the shower head 5100d facing the substrate 10. The shower head 5100d distributes the process gas supplied from the ceiling wall of the chamber 1000d and supplies the process gas into the processing space 1001d. The shower head 5100d may be made of a metal material. Therefore, an electric layer 4001d may coat on the surface of the shower head 5100d facing the substrate 10, and the electrode 4100d may be on the surface of the dielectric layer 4001d facing the substrate 10, identical or similar to the example embodiment of FIG. 1.

Other configurations, structures, functions, deposition methods, etc. of the substrate treatment apparatus 100d of FIG. 11 may be identical or similar to the other embodiments described above.

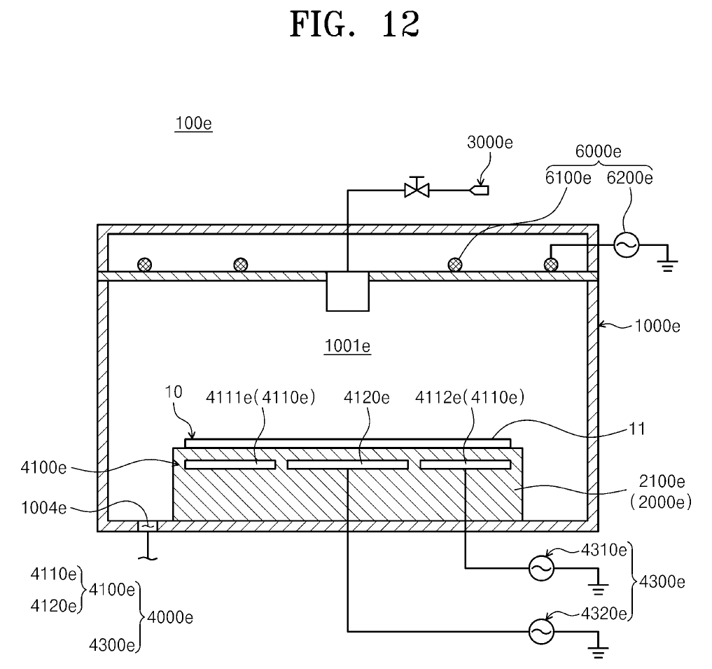

FIG. 12 is a vertical cross-sectional view illustrating a substrate treatment apparatus 100e according to some example embodiments of the present disclosure.

Referring to FIG. 12, the substrate treatment apparatus 100e may be an inductively coupled plasma (ICP) type apparatus. According to some example embodiments, the substrate treatment apparatus 100e may further include a plasma generator 6000e (e.g., plasma generation apparatus).

The plasma generator 6000e may convert process gas supplied into the processing space 1001e into plasma. According to some example embodiments, the plasma generator 6000e may include an antenna 6100e and a source power 6200e.

The antenna 6100e may be on the outside of the ceiling wall of the chamber 1000e. The antenna 6100e may include a plurality of antenna coils having a ring shape. However, the structure of the antenna 6100e may be not limited thereto.

The source power 6200e may be an RF power source and supply RF power to the antenna 6100e. The powered antenna 6100e may form an electromagnetic field in the processing space 1001e of the chamber 1000e. The process gas in the processing space 1001e may be converted into a plasma state by the electromagnetic field. The amount of plasma generated may be controlled by controlling the intensity of the power of the source power 6200e.

The gas supplier 3000e may supply the process gas into the processing space 1001e through a nozzle installed on the ceiling wall of the chamber 1000e.

The substrate support 2000e may include a stage 2100e. A substrate 10 may be placed on the upper surface of the stage 2100e. The substrate 10 on the stage 2100e may be positioned so that the back side surface 11 of the substrate 10 is exposed upward.

In some example embodiments, the electric field generator 4000e may supply a self-bias voltage to the substrate 10. The electrode 4100e may be embedded in the stage 2100e. As in the example embodiments described above, the degree to which plasma generated in the processing space 1001e is induced by each electrode 4110e, 4120e may vary depending on the intensity of RF power supplied to the electrodes 4110e, 4120e. That is, the electrode to which a greater RF power is supplied may induce more plasma compared to the electrode to which a smaller RF power is supplied, thus the electrode to which a greater RF power is supplied may form a higher density deposition layer compared to an electrode to which a smaller RF power is supplied. Therefore, As in the example embodiments described above, warpage that occurred of may occur in the substrate 10 may be compensated for or prevented by controlling the intensity of RF power supplied to each of the electrodes 4110e, 4120e differently.

Other configurations, structures, functions, deposition methods, etc. of the substrate treatment apparatus 100e of FIG. 12 may be identical or similar to the other embodiments described above.

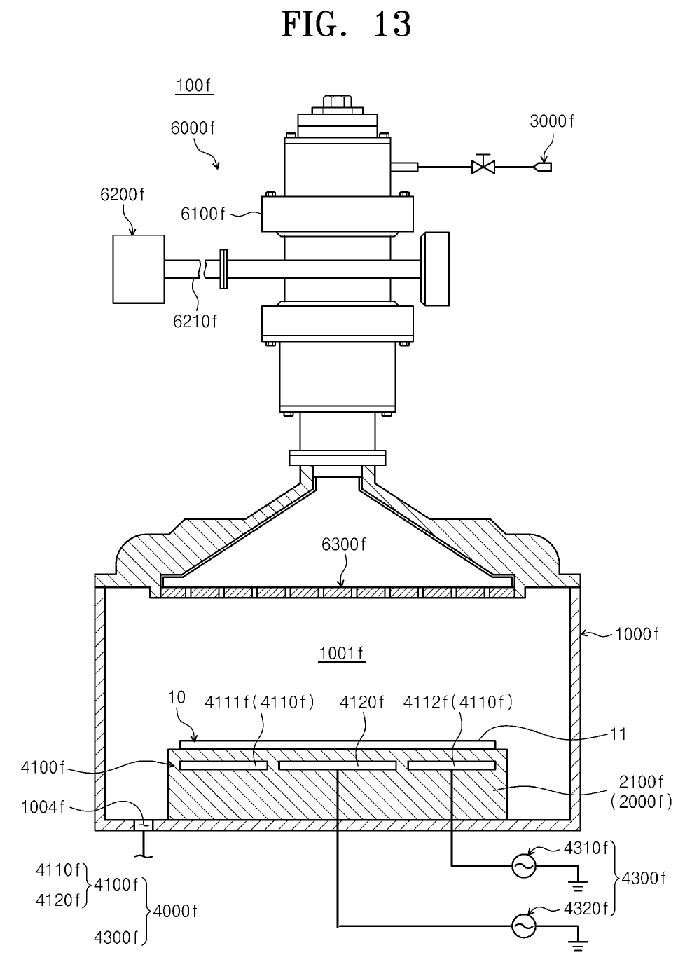

FIG. 13 is a vertical cross-sectional view illustrating a substrate treatment apparatus 100f according to some example embodiments of the present disclosure.

Referring to FIG. 13, the substrate treatment apparatus 100f may be a remote plasma type. For example, the substrate treatment apparatus 100f may be a remote plasma type apparatus that generates plasma outside the processing space 1001f using microwaves and supplies the plasm into the processing space 1001f. Alternatively, the substrate treatment apparatus 100f may be another remote plasma type, such as an inductively coupled plasma (ICP) type.

According to some example embodiments, the substrate treatment apparatus 100f may further include a plasma generator 6000f. The plasma generator 6000f may convert a process gas into plasma. According to some example embodiments, the plasma generator 6000f may include a plasma chamber 6100f, a magnetron 6200f, a wave guide 6210f and a baffle 6300f.

The plasma chamber 6100f may have a space in the plasma chamber 6100f where a process gas is converted into plasma. The plasma chamber 6100f may be above the chamber 1000f. The bottom of the plasma chamber 6100f may be connected to the open ceiling of the chamber 1000f. The gas supplier 3000f may supply a process gas into the plasma chamber 6100f. The magnetron 6200f may generate microwave for plasma generation. The plasma chamber 6100f may be connected to the magnetron 6200f through the wave guide 6210f. Process gas supplied into the plasma chamber 6100f by the gas supplier 3000f may react to microwave generated from the magnetron 6200f to generate plasma inside the plasma chamber 6100f. The plasma generated inside the plasma chamber 6100f may be supplied into the processing space 1001f through the ceiling of the chamber 1000f. The plasma supplied from the plasma chamber 6100f to the processing space 1001f may be distributed by the baffle 6300f and supplied to the processing space 1001f through the baffle 6300f.

Other features of the substrate support 2000f and the electric field generator 4000f may be identical or similar to those of the substrate treatment apparatus 100e of FIG. 12.

Other configurations, structures, functions, deposition methods, etc. of the substrate treatment apparatus 100f of FIG. 13 may be identical or similar to the other embodiments described above.

As described above, the electric field generators and substrate treatment apparatuses according to the example embodiments of the present disclosure may compensate for or prevent warpages of various shapes of the substrate by supplying RF powers of different intensities to each of a plurality of electrodes arranged spaced apart from each other to vary the density of the deposition layer deposited by each of the electrodes.

While the present disclosure has been described with reference to embodiments thereof, it will be apparent to those of ordinary skill in the art that various changes and modifications can be made thereto without departing from the spirit and scope of the present disclosure as set forth in the following claims.

What is claimed is:

1. An electric field generator configured to generate an electric field in a processing space where a substrate is processed, comprising:
an electrode having a surface facing a substrate in the processing space; and
a power supply that supplies RF power to the electrode,
wherein the electrode comprises a first electrode and a second electrode that are spaced apart from each other,
wherein the power supply portion comprises:
a first power supply that supplies RF power to the first electrode; and
a second power supply that supplies RF power to the second electrode,
wherein the first power supply supplies RF power at a first intensity and the second power supply supplies RF power at a second intensity different from the first intensity.

2. The electric field generator of claim 1,
wherein the first electrode comprises a first side electrode and a second side electrode that are arranged to be spaced apart from each other along a direction, and the first side electrode and the second side electrode are electrically connected to each other,
wherein the second electrode is between the first side electrode and the second side electrode.

3. The electric field generator of claim 2,
wherein a boundary area between the first side electrode and the second electrode, and a boundary area between the second side electrode and the second electrode have straight line structures parallel to each other.

4. The electric field generator of claim 2,
wherein a boundary area between the first side electrode and the second electrode, and a boundary area between the second side electrode and the second electrode have curved structures convexly bent toward each other.

5. The electric field generator of claim 2,
wherein the electrode further comprises a third electrode that surrounds the first electrode and the second electrode, and the third electrode is spaced apart from the first electrode and the second electrode,
wherein the power supply further comprises a third power supply that supplies RF power to the third electrode,
wherein the third power supply supplies RF power of a third intensity that is different from the first intensity and the second intensity.

6. The electric field generator of claim 1,
wherein the electric field generator further comprises a ground electrode that faces the electrode with the substrate interposed therebetween and the ground electrode is grounded.

7. A substrate treatment apparatus configured to treat a substrate, the substrate treatment apparatus comprising:
a chamber having a processing space in which a substrate is processed;
a substrate support that supports a substrate within the processing space;
a gas supplier that supplies a process gas; and
an electric field generator that generates an electric field in the processing space,
wherein the electric field generation generator comprises:
an electrode having a surface facing a substrate in the processing space; and
a power supply that supplies RF power to the electrode,
wherein the electrode comprises a first electrode and a second electrode that are spaced apart from each other,
wherein the power supply comprises:
a first power supply that supplies RF power to the first electrode; and
a second power supply that supplies RF power to the second electrode,
wherein the first power supply supplies RF power at a first intensity and the second power supply supplies RF power at a second intensity different from the first intensity.

8. The substrate treatment apparatus of claim 7,
wherein the first electrode comprises a first side electrode and a second side electrode that are arranged to be spaced apart from each other along a direction, and the first side electrode and the second side electrode are electrically connected to each other,
wherein the second electrode is between the first side electrode and the second side electrode.

9. The substrate treatment apparatus of claim 8,
wherein a boundary area between the first side electrode and the second electrode, and a boundary area between the second side electrode and the second electrode have straight line structures parallel to each other.

10. The substrate treatment apparatus of claim 8,
wherein a boundary area between the first side electrode and the second electrode, and a boundary area between the second side electrode and the second electrode have curved structures convexly bent toward each other.

11. The substrate treatment apparatus of claim 8,
wherein the electrode further comprises a third electrode that surrounds the first electrode and the second electrode, and the third electrode is spaced apart from the first electrode and the second electrode,
wherein the power supply further comprises a third power supply that supplies RF power to the third electrode,
wherein the third power supply supplies RF power of a third intensity that is different from the first intensity and the second intensity.

12. The substrate treatment apparatus of claim 7,
wherein the electric field generator further comprises a ground electrode that faces the electrode with the substrate interposed therebetween, and the ground electrode is grounded.

13. The substrate treatment apparatus of claim 7, further comprising:
a plasma generator that converts the process gas into plasma,
wherein the substrate support comprises a stage that supports a substrate on a surface of the stage,
wherein the electrode is embedded in the stage.

14. A substrate treatment apparatus configured to treat one or more substrates, the substrate treatment apparatus comprising:
a chamber having a processing space in which a substrate is processed;
a substrate support that supports a substrate within the processing space;
a gas supplier that supplies a process gas;
a plasma generator that converts the process gas into plasma; and
an electric field generator that generates an electric field in the processing space,
wherein the substrate support comprises a stage that supports a substrate on a surface of the stage,
wherein the electric field generator comprises:
an electrode having a surface facing a substrate in the processing space and embedded in the stage; and
a power supply that supplies RF power to the electrode,
wherein the electrode comprises a first electrode and a second electrode that are spaced apart from each other,
wherein the power supply comprises:
a first power supply that supplies RF power to the first electrode; and
a second power supply that supplies RF power to the second electrode,
wherein the first power supply supplies RF power at a first intensity and the second power supply supplies RF power at a second intensity different from the first intensity.

15. The substrate treatment apparatus of claim 14,
wherein the first electrode comprises a first side electrode and a second side electrode that are arranged to be spaced apart from each other along a direction, and the first side electrode and the second side electrode are electrically connected to each other,
wherein the second electrode is between the first side electrode and the second side electrode.

16. The substrate treatment apparatus of claim 15,
wherein a boundary area between the first side electrode and the second electrode, and a boundary area between the second side electrode and the second electrode have straight line structures parallel to each other.

17. The substrate treatment apparatus of claim 15,
wherein a boundary area between the first side electrode and the second electrode, and a boundary area between the second side electrode and the second electrode have curved structures convexly bent toward each other.

18. The substrate treatment apparatus of claim 15,
wherein the electrode further comprises a third electrode that surrounds the first electrode and the second electrode, and the third electrode is spaced apart from the first electrode and the second electrode,
wherein the power supply further comprises a third power supply that supplies RF power to the third electrode,
wherein the third power supply supplies RF power of a third intensity different from the first intensity and the second intensity.

19. The substrate treatment apparatus of claim 14,
wherein the plasma generator comprises:
an antenna that is outside the chamber; and
a source power that supplies RF power to the antenna.

20. The substrate treatment apparatus of claim 19,
wherein the electric field generator supplies self-bias voltage to the substrate.
